(19) United States
(12) Patent Application Publication
(10) Pub. No.: US 2023/0395053 A1
(43) Pub. Date: Dec. 7, 2023

(54) SOUND PROCESSING COMPONENT AND STRING INSTRUMENT EMPLOYING COMPONENT

(71) Applicant: GuangZhou LAVA MUSIC LLC., Guangzhou (CN)

(72) Inventors: ZI-TIAN LU, Guangzhou (CN); XIN-GONG XU, Guangzhou (CN); SHUAI YIN, Guangzhou (CN)

(21) Appl. No.: 18/202,903

(22) Filed: May 27, 2023

(30) Foreign Application Priority Data
Jun. 7, 2022 (CN) 202210639633.1

(51) Int. Cl. G10H 3/18; G10D 1/08; G10H 1/00

(52) U.S. Cl. CPC G10H 3/188; G10D 1/085; G10H 1/0066; G10H 1/0091; G10H 2240/311; G10H 2220/461; G10H 2240/285; G10H 2240/145; H03F 3/183

(57) ABSTRACT

A sound processing component applied to a string instrument for providing multiple playing forms and a MIDI function. An acquisition module acquires vibration information of multiple strings and outputs analog signals, and a first amplification and filter module amplifies the analog signals and filters the analog signals. A first conversion module converts the analog signals into digital signals, and a processing module identifies playing information of the digital signals, converts the digital signals to MIDI data based on the playing information, converts the MIDI data to audio data, and add audio effects for the audio data. A second conversion module converts the audio data with the audio effects into analog audio signals, and a second amplification and filter module amplifies the analog audio signals, filters the analog audio signals, and transmit the filtered analog audio signals to a loudspeaker. The string instrument is also provided.

### TECHNICAL FIELD

The subject matter herein generally relates to string instruments.

### BACKGROUND

Electric musical instruments that combine traditional musical instruments with electronic systems have become popular, such as electric guitars and electric basses. However, current electric musical instruments are still unable to process musical instrument digital interface (MIDI) signals, or provide single sound effect, so that the playability and practicality of the electric musical instruments are greatly reduced.

### BRIEF DESCRIPTION OF THE DRAWINGS

Implementations of the present technology will now be described, by way of example only, with reference to the attached figures.

FIG. 1 is a structural diagram of an embodiment of a string instrument according to the present disclosure.

FIG. 2A is a block diagram of an embodiment of a sound processing component of the string instrument of FIG. 1.

FIG. 2B is a block diagram of another embodiment of a sound processing component of the string instrument of FIG. 1.

FIG. 3 is an embodiment of a circuit diagram of the sound processing component of the string instrument of FIG. 1.

FIG. 4 is another embodiment of a circuit diagram of the sound processing component of the string instrument of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure. It should be noted that references to “an” or “one” embodiment in this disclosure are not necessarily to the same embodiment, and such references mean “at least one”.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

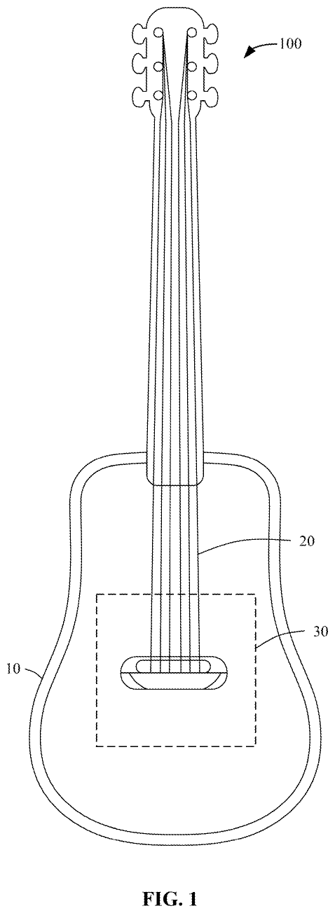

FIG. 1 illustrates one exemplary embodiment of a string instrument 100. The string instrument 100 comprises an instrument body 10, a plurality of strings 20, and a sound processing component 30. The instrument body 10 is connected with the plurality of strings 20 and the sound processing component 30. For example, the plurality of strings 20 can be arranged on the instrument body 10, the sound processing component 30 can be arranged in the instrument body 10.

For example, the instrument body 10 comprises a cavity, the sound processing component 30 is arranged in the cavity.

The number of strings 20 can be set according to an actual requirement, for example, as shown in FIG. 1, the string instrument 100 comprises six strings 20. The sound processing component 30 is configured to convert vibration information of the six string 20 into electrical signals to drive a loudspeaker for playback.

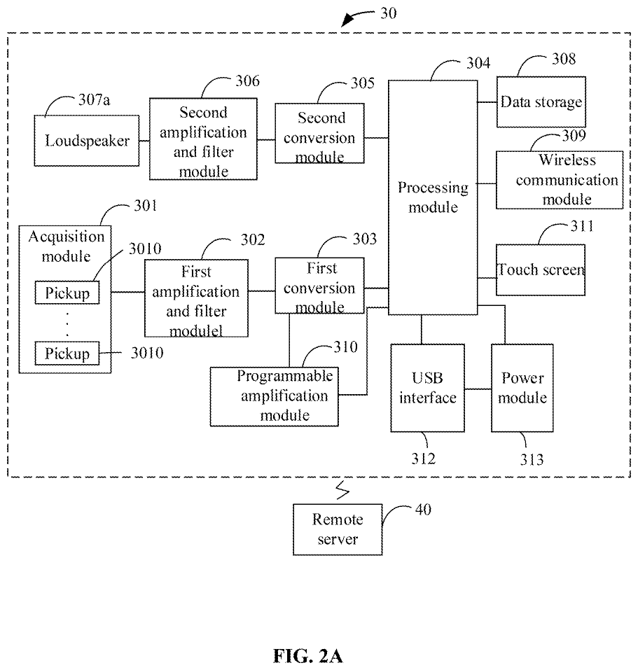

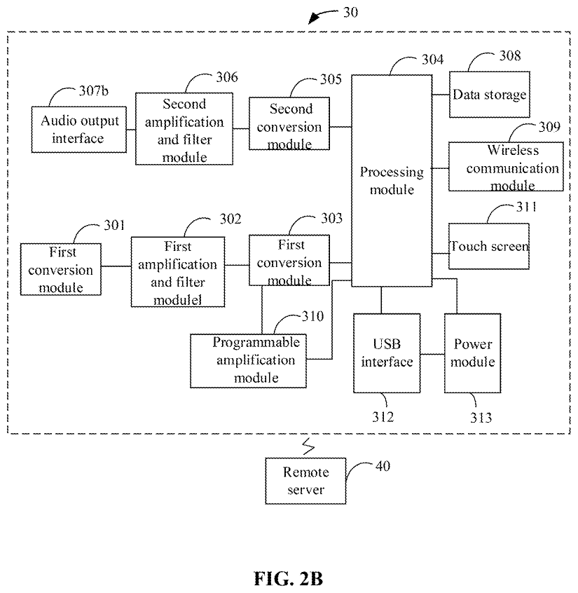

Referring to FIGS. 2A and 2B, the sound processing component 30 can comprise an acquisition module 301, a first amplification and filter module 302, a first conversion module 303, a processing module 304, a second conversion module 305, and a second amplification and filter module 306.

The acquisition module 301 is configured to acquire the vibration information of the plurality of strings 20 and output analog signals. For example, the acquisition module 301 can comprise a plurality of pickups 3010. The number of the pickups 3010 can be equivalent to the number of the strings 20. Each of the plurality of pickups 3010 can acquire vibration information of one string 20, and convert the vibration information into electrical signals. The plurality of pickups 3010 can be divided pickups of magnetic sensing type or divided pickups of pressure sensing type.

The first amplification and filter module 302 is coupled to the acquisition module 301, and configured to amplify the analog signals and filter the analog signals, and output the filtered analog signals. For example, the analog signals may comprise high-frequency noises, the first amplification and filter module 302 can filter the high-frequency noises comprised in the analog signals. The first conversion module 303 is coupled to the first amplification and filter module 302, and configured to convert the filtered analog signals output by the first amplification and filter module 302 (the analog signals amplified and filtered by the first amplification and filter module 302) into digital signals.

The processing module 304 is coupled to the first conversion module 303, and configured to identify playing information of the digital signals. The processing module 304 is further configured to convert the digital signals to musical instrument digital interface (MIDI) data based on the playing information of the digital signals. The playing information can comprise strumming position information of the strings 20 corresponding to the digital signals.

For example, the acquisition module 301 can acquire a vibration frequency of each of the plurality of strings 20, and the processing module 304 can identify strumming position of a player by comparing the acquired vibration frequency with vibration frequencies of the plurality of strings 20 to obtain the strumming position information corresponding to the digital signals. The processing module 304 may also convert the MIDI data into audio data based on a predetermined audio source library, which is convenient for driving the loudspeaker 307a. The predetermined audio source library can be stored in the string instrument 100 or in a remote server 40 (for example, a cloud server). The string instrument 100 can communicate with the remote server 40.

In one embodiment, the processing module 304 is further configured to process the audio data to add the audio effects to drive the loudspeaker 307a to output a performance sound such as imitating pianos, erhus, violins, or other instruments, or with a series of sound effects such as reverbs, chorus, low octaves, high octaves, etc., so that the string instrument 100 can achieve a variety of performance forms, a playability of the string instrument 100 can be improved.

The second conversion module 305 is coupled to the processing module 304, and configured to convert the audio data with the audio effects into analog audio signals. The second amplification and filter module 306 is coupled to the second conversion module 305, and configured to amplify the analog audio signals, filter the analog audio signals, and transmit the filtered analog audio signals to the loudspeaker 307a for playback.

In one embodiment, as shown in FIG. 2A, the loudspeaker 307a is integrated with the sound processing component 30, the loudspeaker 307a is coupled to the second amplification and filter module 306. The loudspeaker 307a can also be set independently of the string instrument 100. As shown in FIG. 2B, the sound processing component 30 comprises an audio output interface 307b for connecting an external loudspeaker. The audio output interface 307b is coupled to the second amplification and filter module 306, the audio output interface 307b can transmit the analog audio signals amplified and filtered by the second amplification and filter module 306 to the external loudspeaker for playback.

In one embodiment, the sound processing component 30 can further comprise a data storage 308 and a wireless communication module 309. The data storage 308 can be configured to store an audio effects library, the predetermined audio source library, codes and data required for the processing module 304, etc. When the predetermined audio source library is stored in the remote server 40, the predetermined audio source library can be accessible via the wireless communication module 309. For example, the processing module 304 can call the predetermined audio source library stored in the remote server 40 by the wireless communication module 309 to convert the MIDI data into the audio data.

In one embodiment, the processing module 304 is further configured to control the wireless communication module 309 to transmit the MIDI data and information of audio sources corresponding to the MIDI data to the remote server 40. Then, users can access the remote server 40 through computers, mobile phones, and other devices to view, edit, and share the MIDI data and/or the audio sources corresponding to the MIDI data.

In one embodiment, the sound processing component 30 can further comprise a programmable amplification module 310. The programmable amplification module 310 is coupled to the first conversion module 303 and the processing module 304. The processing module 304 is further configured to set amplification parameters of the programmable amplification module 310, the programmable amplification module 310 is configured to amplify the analog signals amplified and filtered by the first amplification and filter module 302 again, to realize a secondary amplification of the analog signals output by the pickups 3010. The first conversion module 303 is configured to convert the analog signals amplified by the programmable amplification module 310 into the digital signals. Then, the first amplification and filter module 302, the programmable amplification module 310, and the first conversion module 303 can adapt to different playing scenes of playing information acquisition and conversion.

In one embodiment, the amplification parameters can comprise a gain of the programmable amplification module 310, the processing module 304 can set the gain of the programmable amplification module 310 based on a voltage of the analog signals output by the first amplification and filter module 302. For example, a current voltage detection circuit can be coupled between the first amplification and filter module 302 and the processing module 304, the processing module 304 can be a processor integrated an analog digital converter (ADC).

In one embodiment, the sound processing component 30 further comprises a touch screen 311, the touch screen 311 is coupled to the processing module 304. The touch screen 311 is configured to receive instructions of setting up the audio effects, and the processing module 304 is further configured to process the audio data according to the instructions. For example, the processing module 304 can run a musical instrument operating system, the musical instrument operating system comprises setting interfaces of playback effects, supports a variety of playback effect selections or customizations, the touch screen 311 can set playback effect of the string instrument 100 based on touch commands of a player, so that the player can play the string instrument 100 to produce a sound such as imitating pianos, erhus, violins, or other musical instruments, or produce a sound such as reverbs, chorus, low octaves, high octaves, or other sound effects.

In one embodiment, the sound processing component 30 further comprises a universal serial bus (USB) interface 312, the USB interface 312 is coupled to the processing module 304. The processing module 304 is further configured to control the USB interface 312 to transmit the MIDI data and the information of audio sources corresponding to the MIDI data to an external electronic device that is coupled with the USB interface 312. For example, the external electronic device can be mobile phones, computers, etc.

In one embodiment, the sound processing component 30 further comprises a power module 313, to supply power for electronic elements of the sound processing component 30. The power module 313 may comprise a lithium battery and a power management chip, the power module 313 is coupled to the USB interface 312, and the lithium battery is charged by connecting an external power source through the USB interface 312.

In one embodiment, the string instrument 100 can synchronize pickup data of the pickups 3010 to internet network through the wireless communication module 309, to realize a function of remote interaction of playing. The string instrument 100 can also call and load audio sources of the remote server 40 to achieve converting the MIDI data into the audio data, or sharing the MIDI data, or other functions.

In addition to use the touch screen 311 for human-computer interaction, the string instrument 100 can also achieve cloud interaction through the network. For example, the MIDI data played by the user and data of the audio effects set by the user can be stored to the cloud (for example remote server 40), the string instrument 100 can also call cloud algorithm of the cloud to process the audio data, to add one or more type of audio effects for the audio data. Timbres, audio effects, or other audio parameters can be created on other devices to synchronize to the cloud, or current timbres, current audio effects, or other audio parameters can be edited on other devices to synchronize to the cloud, and the timbres and the audio effects stored in the cloud can be synchronized to the string instrument 100.

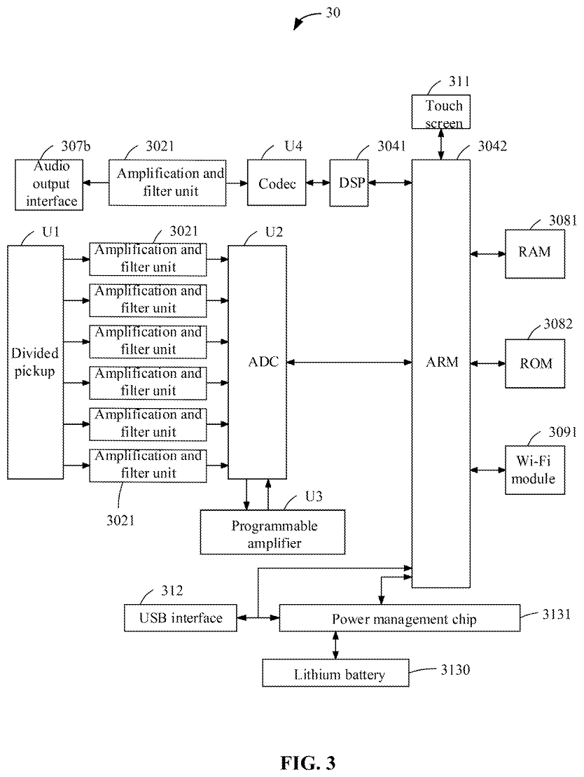

FIG. 3 illustrates one exemplary embodiment of a circuit diagram of the sound processing component 30.

The string instrument 100 comprises six strings 20 for example, the acquisition module 301 can comprises a divided pickup U1, a type of the divided pickup U1 can be the magnetic sensing type or the pressure sensing type. The divided pickup U1 can integrated six pickups correspond to acquire vibration information of the six strings 20 respectively.

The first amplification and filter module 302 can comprise a plurality of amplification and filter units 3021 corresponding to the plurality of pickups 3010. The number of the pickups amplification and filter units 3021 can be equivalent to the number of the strings 20. One pickup can correspond to one amplification and filter unit 3021, each amplification and filter unit 3021 may comprise an operational amplifier and a capacitor, to amplify and filter the analog signals output by the corresponding pickup.

The first conversion module 303 can comprise an ADC U2, the ADC U2 may have six analog-digital conversion channels, for corresponding to couple with the six amplification and filter units 3021, to realize converting the analog signals amplified and filtered by the six amplification and filter units 3021 into the digital signals. The processing module 304 can perform a time-sharing multiplexing control of the six analog-digital conversion channels of the ADC U2. Then, the processing module 304 can process one channel of digital signals at a time, which is convenient for identifying the playing information of the digital signals, and converting the digital signals into the MIDI data.

The programmable amplification module 310 can comprise a programmable amplifier U3. The programmable amplifier U3 is coupled to the processing module 304 and the ADC U2. The processing module 304 can set amplification parameters of the programmable amplifier U3, the programmable amplifier U3 can amplify the analog signals amplified and filtered by the first amplification and filter unit 3021 again, to realize a secondary amplification of the analog signals output by the divided pickup U1. For example, when the programmable amplifier U3 is enabled for secondary amplification, the ADC U2 receives signals from the amplification and filter unit 3021 and inputs to the programmable amplifier U3 for amplifying, and then enters the ADC U2 for analog-digital converting.

The processing module 304 comprises a digital signal processor (DSP) 3041 and an advanced reduced instruction set computer machine (ARM) 3042. The ARM 3042 is coupled to the ADC U2 and the DSP 3041, the ARM 3042 is configured to identify the playing information of the digital signals based on a predetermined identification algorithm, and convert the digital signals to the MIDI data based on the playing information of the digital signals. For example, the ARM 3042 can identify the strumming position according to the vibration frequencies of different strings, and realize converting received digital signals into the MIDI data. The ARM 3042 can also call the predetermined audio source library that is stored locally or in the cloud to convert the MIDI data into the audio data, for subsequently drive the loudspeaker for playback. The ARM 3042 can also be coupled to a clock circuit, the clock circuit can provide operating timing for the ARM 3042.

The wireless communication module 309 can comprise a wireless fidelity (Wi-Fi) module and/or a 5th generation mobile network (5G) module. As shown in FIG. 3, the wireless communication module 309 comprises the Wi-Fi module 3091 for example, the MIDI data and the information of audio sources corresponding to the MIDI data may be synchronized to the cloud by the Wi-Fi module 3091. Then, the users can access the cloud through computers, mobile phones, or other electric devices to view, edit, share, synchronize MIDI data and/or the information of audio source.

The DSP 3041 is coupled to the ARM 3042, the DSP 3041 can process the audio data to add audio effects, a series of playback effects can be added into the audio data. So that the player can play the string instrument 100 to produce a sound such as imitating pianos, erhus, violins, or other musical instruments, or produce a sound such as reverbs, chorus, low octaves, high octaves, or other sound effects.

The second conversion module 305 can comprise a coder-decoder (codec) U4, the codec U4 can convert the audio data with the audio effects into the analog audio signals. The codec U4 can integrate an analog-digital conversion function and a digital-analog conversion function, which is convenient to realize the analog-digital conversion of analog signals of the audio source input interface (for example microphone interface) and transmit it to the DSP 3041 for processing, or to realize the digital-analog conversion of digital signals of the DSP 3041 and transmit it to the audio output interface.

The second amplification and filter module 306 may comprise one amplification and filter unit 3021, to realize amplifying the analog audio signals and filtering noise signals comprised in the analog audio signals. The analog audio signal processed by the second amplification and filter module 306 can be transmitted to an external loudspeaker for playback through the audio output interface 307. When the string instrument 100 integrates the loudspeaker, the analog audio signal processed by the second amplification and filter module 306 can be directly transmitted to the loudspeaker for playback.

The data storage 308 can comprise a random access memory (RAM) 3081 and a read only memory (ROM) 3082. The RAM 3081 and the ROM 3082 can be configured to store the audio effects library, the predetermined audio source library, codes and data required for the ARM 3042, etc. The power module 313 may comprise the lithium battery 3130 and the power management chip 3131, the power module 313 is coupled to the USB interface 312, and the lithium battery 3130 is charged by connecting an external power source through the USB interface 312. The power management chip 3131 can manage the lithium battery 3130 of charging and discharging.

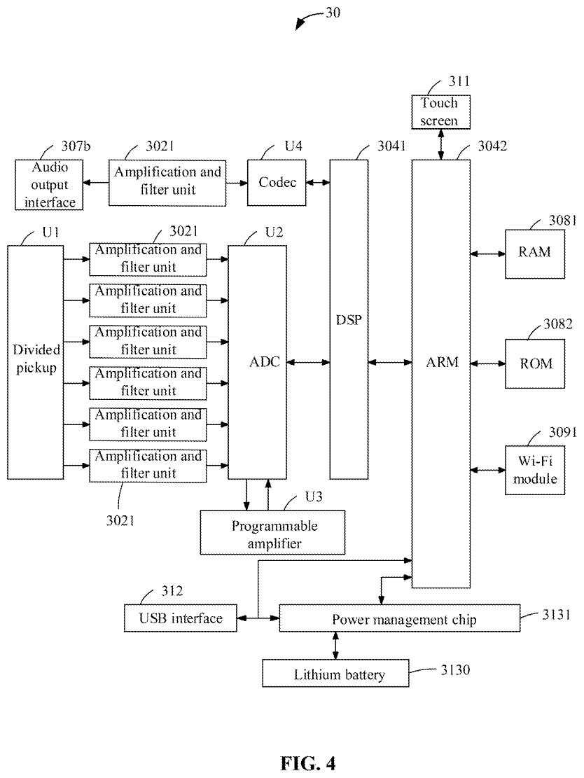

In one embodiment, referring to FIG. 4, the DSP 3041 is coupled to the ARM 3042, the ADC U2, and the codec U4. The DSP 3041 can also be coupled to the ADC U2 and the codec U4. The DSP 3041 is configured to identify the playing information of the digital signals and convert the digital signals to the MIDI data based on the playing information of the digital signals. The ARM 3042 is coupled to the DSP 3041, the ARM 3042 is configured to convert the MIDI data to the audio data based on the predetermined audio source library stored locally or in the cloud. The DSP 3041 is further configured to process the audio data to add a specified set of audio effects.

The above string instrument 10 break through limitations of single performance form of traditional string instruments, the playability and the practicality of the string instrument 10 are effectively improved, and the function of MIDI of the string instrument 10 can be realized.

The exemplary embodiments shown and described above are only examples. Many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

What is claimed is:

1. A string instrument comprising:
an instrument body;
a plurality of strings arranged on the instrument body; and
a sound processing component arranged in the instrument body, wherein the sound processing component comprises:
an acquisition module configured to acquire vibration information of the plurality of strings and output analog signals based on the acquired vibration information;
a first amplification and filter module coupled to the acquisition module, the first amplification and filter module being configured to amplify the analog signals, filter the analog signals, and output the filtered analog signals;
a first conversion module coupled to the first amplification and filter module, the first conversion module being configured to convert the filtered analog signals output by the first amplification and filter module into digital signals;
a processing module coupled to the first conversion module, the processing module being configured to identify playing information of the digital signals, wherein the processing module is further configured to convert the digital signals to musical instrument digital interface (MIDI) data based on the playing information of the digital signals, and convert the MIDI data to audio data based on a predetermined audio source library, and the processing module processes the audio data to add audio effects;
a second conversion module coupled to the processing module, the second conversion module being configured to convert the audio data with the audio effects into analog audio signals; and
a second amplification and filter module coupled to the second conversion module, the second amplification and filter module being configured to amplify the analog audio signals, filter the analog audio signals, and transmit the filtered analog audio signals to a loudspeaker.

2. The string instrument of claim 1, wherein the acquisition module comprises a plurality of pickups, the first amplification and filter module comprises a plurality of amplification and filter units respectively corresponding to the plurality of pickups, the first conversion module comprises a plurality of analog-digital conversion channels respectively corresponding to the plurality of pickups, and the processing module is configured to perform a time-sharing multiplexing control of the plurality of analog-digital conversion channels, to control the first conversion module converting the analog signals of the plurality of pickups into the digital signals.

3. The string instrument of claim 1, wherein the sound processing component further comprises a data storage and a wireless communication module, and the predetermined audio source library is stored in the data storage or accessible via the wireless communication module.

4. The string instrument of claim 3, wherein the processing module is further configured to control the wireless communication module to transmit the MIDI data and information of audio sources corresponding to the MIDI data to a remote server.

5. The string instrument of claim 1, wherein the sound processing component further comprises a programmable amplification module, the programmable amplification module is coupled to the first conversion module and the processing module, the processing module is further configured to set amplification parameters of the programmable amplification module, the programmable amplification module is configured to amplify the analog signals output by the first amplification and filter module, and the first conversion module is configured to convert the analog signals amplified by the programmable amplification module into the digital signal.

6. The string instrument of claim 1, wherein the sound processing component further comprises a touch screen, the touch screen is coupled to the processing module, the touch screen is configured to receive instructions of setting up the audio effects, and the processing module is further configured to process the audio data according to the instructions.

7. The string instrument of claim 1, wherein the processing module comprises a digital signal processor (DSP) and an advanced reduced instruction set computer machine (ARM), the ARM is coupled to the first conversion module, the ARM is configured to identify the playing information of the digital signals, convert the digital signals to the MIDI data based on the playing information of the digital signals, and further convert the MIDI data to the audio data based on the predetermined audio source library, the DSP is coupled to the ARM, and the DSP is configured to process the audio data to add the audio effects.

8. The string instrument of claim 1, wherein the processing module comprises a digital signal processor (DSP) and an advanced reduced instruction set computer machine (ARM), the DSP is coupled to the first conversion module, the DSP is configured to identify the playing information of the digital signals and convert the digital signals to the MIDI data based on the playing information of the digital signals, the ARM is coupled to the DSP, the ARM is configured to convert the MIDI data to the audio data based on the predetermined audio source library, and the DSP is further configured to process the audio data to add the audio effects.

9. The string instrument of claim 1, wherein the loudspeaker is integrated with the sound processing component; or the sound processing component comprises an audio output interface configured for connecting to the loudspeaker.

10. The string instrument of claim 1, wherein the sound processing component further comprises a universal serial bus (USB) interface, the USB interface is coupled to the processing module, the processing module is further configured to control the USB interface to transmit the MIDI data and information of audio sources corresponding to the MIDI data to an external electronic device that is coupled with the USB interface.

11. A sound processing component applied to a string instrument, the string instrument comprising a plurality of strings, the sound processing component comprising:
an acquisition module configured to acquire vibration information of the plurality of strings and output analog signals based on the acquired vibration information;
a first amplification and filter module coupled to the acquisition module, the first amplification and filter module being configured to amplify the analog signals, filter the analog signals, and output the filtered analog signals;
a first conversion module coupled to the first amplification and filter module, the first conversion module being configured to convert the filtered analog signals output by the first amplification and filter module into digital signals;
a processing module coupled to the first conversion module, the processing module being configured to identify playing information of the digital signals, wherein the processing module is further configured to convert the digital signals to musical instrument digital interface (MIDI) data based on the playing information of the digital signals, and convert the MIDI data to audio data based on a predetermined audio source library, and the processing module processes the audio data to add audio effects;
a second conversion module coupled to the processing module, the second conversion module being configured to convert the audio data with the audio effects into analog audio signals; and
a second amplification and filter module coupled to the second conversion module, the second amplification and filter module being configured to amplify the analog audio signals, filter the analog audio signals, and transmit the filtered analog audio signals to a loudspeaker.

12. The sound processing component of claim 11, wherein the acquisition module comprises a plurality of pickups, the first amplification and filter module comprises a plurality of amplification and filter units respectively corresponding to the plurality of pickups, the first conversion module comprises a plurality of analog-digital conversion channels respectively corresponding to the plurality of pickups, and the processing module is configured to perform a time-sharing multiplexing control of the plurality of analog-digital conversion channels, to control the first conversion module converting the analog signals of the plurality of pickups into the digital signals.

13. The sound processing component of claim 11, further comprising a data storage and a wireless communication module, wherein the predetermined audio source library is stored in the data storage or accessible via the wireless communication module.

14. The sound processing component of claim 13, wherein the processing module is further configured to control the wireless communication module to transmit the MIDI data and information of audio sources corresponding to the MIDI data to the remote server.

15. The sound processing component of claim 11, further comprising a programmable amplification module, wherein the programmable amplification module is coupled to the first conversion module and the processing module, the processing module is further configured to set amplification parameters of the programmable amplification module, the programmable amplification module is configured to amplify the analog signals output by the first amplification and filter module, and the first conversion module is configured to convert the analog signals amplified by the programmable amplification module into the digital signals.

16. The sound processing component of claim 11, further comprising a touch screen, wherein the touch screen is coupled to the processing module, the touch screen is configured to receive instructions of setting up the audio effects, and the processing module is further configured to process the audio data according to the instructions.

17. The sound processing component of claim 11, wherein the processing module comprises a digital signal processor (DSP) and an advanced reduced instruction set computer machine (ARM), the ARM is coupled to the first conversion module, the ARM is configured to identify the playing information of the digital signals, convert the digital signals to the MIDI data based on the playing information of the digital signals, and further convert the MIDI data to the audio data based on the predetermined audio source library, the DSP is coupled to the ARM, and the DSP is configured to process the audio data to add the audio effects.

18. The sound processing component of claim 11, wherein the processing module comprises a digital signal processor (DSP) and an advanced reduced instruction set computer machine (ARM), the DSP is coupled to the first conversion module, the DSP is configured to identify the playing information of the digital signals and convert the digital signals to the MIDI data based on the playing information of the digital signals, the ARM is coupled to the DSP, the ARM is configured to convert the MIDI data to the audio data based on the predetermined audio source library, and the DSP is further configured to process the audio data to add the audio effects.

19. The sound processing component of claim 11, wherein the loudspeaker is integrated with the sound processing component; or the sound processing component comprises an audio output interface configured for connecting to the loudspeaker.

20. The sound processing component of claim 11, further comprising a universal serial bus (USB) interface, wherein the USB interface is coupled to the processing module, the processing module is further configured to control the USB interface to transmit the MIDI data and information of audio sources corresponding to the MIDI data to an external electronic device that is coupled with the USB interface.
